(19) United States
(12) Patent Application Publication
(10) Pub. No.: US 2026/0249400 A1
(43) Pub. Date: Aug. 27, 2026

(54) EIGHT-AXIS SIX-HEAD LINKAGE LASER ENGRAVING MACHINE WITH COOLING CIRCULATION STRUCTURE

(71) Applicant: DONGGUAN DI AO CNC EQUIPMENT CO.,LTD, Dongguan (CN)

(72) Inventor: Xiansong Ye, Huangshi (CN)

(21) Appl. No.: 19/643,776

(22) Filed: Apr. 9, 2026

(30) Foreign Application Priority Data
Dec. 23, 2025 (CN) 202511946388.9

(51) Int. Cl. B23K 26/70; B23K 26/064; B23K 26/08; B23K 26/36; H10W 40/20; H10W 40/25; H10W 40/47

(52) U.S. Cl. CPC B23K 26/703; B23K 26/0648; B23K 26/0853; B23K 26/36; H10W 40/237; H10W 40/253; H10W 40/47

(57) ABSTRACT

The present invention relates to the technical field of laser engraving machines, in particular to an eight-axis six-head linkage laser precision engraving machine with a cooling circulation structure, comprising a machine base, on which a workbench and a laser unit are arranged.

The laser unit comprises a laser base, a laser generating module and a lens; the laser generating module comprises a housing and a distributor, wherein a pump source, a working medium module and a Q-switch module are arranged in the housing, and the three are respectively connected with a first cooling plate, a second cooling plate and a third cooling plate; a main heat dissipation channel is arranged in the housing.

The present invention can dynamically adjust the heat dissipation flow, shorten the preheating time, and adjust the heat dissipation weight of each component in a targeted manner.

### CROSS-REFERENCE TO RELATED APPLICATIONS

This application claims priority to Chinese Patent Application No. 202511946388.9, filed on Dec. 23, 2025, which is hereby incorporated by reference in its entirety.

### TECHNICAL FIELD

The present application relates to the technical field of laser engraving machines, and specifically relates to an eight-axis six-head linkage laser engraving machine with a cooling circulation structure.

### BACKGROUND

In the field of precision machining, laser engraving machines are widely used in fine engraving and forming operations in industries such as electronic components, molds, and jewelry due to advantages of high machining precision and strong controllability of laser engraving machines. As a core energy output component of a laser engraving machine, a working stability and a service life of a solid-state laser directly determine a machining quality and an operating efficiency of the laser engraving machine, and a heat dissipation effect of the solid-state laser is one of key factors affecting performance of the solid-state laser.

Multiple core heat-generating components exist inside a solid-state laser, mainly including a pump source for providing an excitation energy, a Q-switch for controlling a laser pulse output, and a working medium module for realizing a population inversion and generating a laser. During an operation of the solid-state laser, heat generation characteristics of the above heat-generating components have significant differences.

To control a working temperature of a solid-state laser, a cooling liquid circulation heat dissipation is commonly adopted in the prior art, that is, a cooling liquid is transported to a heat dissipation structure of a heat-generating component inside the laser through a circulation pipeline to take away an excess heat. However, current cooling liquid heat dissipation solutions all adopt a fixed flow rate control strategy, that is, regardless of an actual temperature state and heat generation characteristic differences of each heat-generating component of the solid-state laser, the cooling liquid always circulates in a system at a constant flow rate.

The fixed flow rate cooling method is unfavorable for a solid-state laser to quickly reach a working temperature. The solid-state laser needs to operate within a specific temperature range after startup to achieve a stable laser output, while in existing solutions, an initial flow rate of a cooling liquid is relatively large and an initial temperature is relatively low, which forms an excessive cooling effect on each heat-generating component, resulting in a significantly prolonged preheating time from a startup to reaching a rated working temperature of the laser.

In addition, due to significant differences in heat generation characteristics of each heat-generating component, there are also essential differences in a demand for a cooling liquid flow rate, while a fixed flow rate solution cannot perform a targeted adjustment according to a real-time temperature feedback from each component, and cannot influence a weight with different cooling liquid flow rates for the targeted adjustment.

### SUMMARY

An objective of the present application is to provide an eight-axis six-head linkage laser engraving machine with a cooling circulation structure in view of the above deficiencies in the prior art.

The objective of the present application is achieved through the following technical solution: an eight-axis six-head linkage laser engraving machine with a cooling circulation structure, comprising a machine base; the machine base is provided with a worktable and a laser unit; the laser unit is movably disposed on a top of the worktable; the laser unit comprises a laser seat, a laser generation module disposed in the laser seat, and a lens disposed on the laser seat; the lens is disposed at a bottom of the laser generation module;

the laser generation module comprises a housing and a distributor; the distributor is disposed on a top of the housing; the housing is internally provided with a pump source, a working medium module, and a Q-switch module; the pump source is connected with a first cooling plate; the working medium module is connected with a second cooling plate; the Q-switch module is connected with a third cooling plate; the housing is provided with a main heat dissipation channel;

the distributor is internally provided with a main distribution channel; the distributor is provided with a main water inlet and a main water outlet; the main water inlet communicates with a top of the main distribution channel; the main water outlet communicates with a bottom of the main distribution channel; the main water outlet communicates with the main heat dissipation channel; the distributor is internally provided with a first distribution channel communicating with the first cooling plate, a second distribution channel communicating with the second cooling plate, and a third distribution channel communicating with the third cooling plate; the first distribution channel is provided with a first control valve; the second distribution channel is provided with a second control valve; the third distribution channel is provided with a third control valve; the main distribution channel is movably provided with a distribution valve along a length direction; a thermosensitive spring is disposed between the distribution valve and the main distribution channel; and the first distribution channel, the second distribution channel, and the third distribution channel respectively communicate with the main distribution channel.

Further, the distribution valve comprises a blocking portion, a connecting portion, and a separation portion; the connecting portion is disposed between the blocking portion and the separation portion; the blocking portion, the connecting portion, and the separation portion are all cylindrical structures; a radius of the connecting portion is smaller than a radius of the blocking portion; the radius of the connecting portion is smaller than a radius of the separation portion; the blocking portion and the separation portion are sealingly and movably disposed in the main distribution channel; and the blocking portion is configured to block the main water inlet and the main water outlet.

Further, the thermosensitive spring is disposed between an end of the separation portion away from the connecting portion and the main distribution channel; a mixing chamber is formed between the end of the separation portion away from the connecting portion and the main distribution channel; the first distribution channel, the second distribution channel, and the third distribution channel respectively communicate with the mixing chamber; and the distributor is provided with a mixing water outlet communicating with the mixing chamber.

Further, the pump source comprises a substrate and a semiconductor chip disposed on the substrate; the first cooling plate comprises a left cooling plate and a right cooling plate; a top of the left cooling plate communicates with the first distribution channel; a bottom of the left cooling plate communicates with a bottom of the right cooling plate; a top of the housing is provided with a first water inlet communicating with a top of the right cooling plate; and the left cooling plate and the right cooling plate respectively abut against the semiconductor chip.

Further, the housing is internally provided with a second conduit and a third conduit; a top of the housing is provided with a second water inlet and a third water inlet; one end of the second conduit communicates with the second distribution channel; another end of the second conduit communicates with the second water inlet after passing through the second cooling plate; one end of the third conduit communicates with the third distribution channel; and another end of the third conduit communicates with the third water inlet after passing through the third cooling plate.

Further, a top of the distributor is provided with a first adjustment channel, a second adjustment channel, and a third adjustment channel; the first control valve is movably disposed in the first adjustment channel; the second control valve is movably disposed in the second adjustment channel; the third control valve is movably disposed in the third adjustment channel; a bottom of the distributor is provided with a first entry channel communicating with the first cooling plate, a second entry channel communicating with the second cooling plate, and a third entry channel communicating with the third cooling plate; the first entry channel communicates with a bottom of the first adjustment channel; the first distribution channel communicates with a side of the first adjustment channel; the second entry channel communicates with a bottom of the second adjustment channel; the second distribution channel communicates with a side of the second adjustment channel; the third entry channel communicates with a bottom of the third adjustment channel; and the third distribution channel communicates with a side of the third adjustment channel.

Further, a connection between the first entry channel and the first adjustment channel, a connection between the second entry channel and the second adjustment channel, and a connection between the third entry channel and the third adjustment channel are all provided with a conical through hole; the first control valve, the second control valve, and the third control valve each comprise a threaded portion and an adjustment portion disposed at a bottom of the threaded portion; the first adjustment channel, the second adjustment channel, and the third adjustment channel are respectively threadedly connected with the threaded portion; the threaded portion and the adjustment portion are both cylindrical structures; a radius of the adjustment portion is smaller than a radius of the threaded portion; and a bottom of the adjustment portion is provided with a conical pin cooperating with the conical through hole.

Further, the main heat dissipation channel comprises a first heat dissipation channel and a second heat dissipation channel; the pump source is disposed on one side within the housing; another side within the housing is provided with a heat conduction plate; the working medium module and the Q-switch module are both disposed on the heat conduction plate; the first heat dissipation channel is disposed between the substrate and the housing; the second heat dissipation channel is disposed between the heat conduction plate and the housing; a top of the first heat dissipation channel communicates with the main water outlet; a bottom of the first heat dissipation channel communicates with a bottom of the second heat dissipation channel; and a top of the housing is provided with a heat dissipation outlet communicating with a top of the second heat dissipation channel.

Further, the machine base is provided with an X-axis linear module configured to drive the worktable to move along an X-axis direction.

Further, the worktable is provided with a gantry frame; the gantry frame is arranged with six lifting seats along a Y-axis direction; the gantry frame is provided with a Y-axis linear module configured to drive the lifting seats to move along the Y-axis direction; each lifting seat is provided with a laser unit; and each lifting seat is provided with a Z-axis linear module configured to drive the laser unit to move up and down.

Beneficial effects of the present application: The present application achieves a linkage between a thermosensitive spring and a distribution valve. When a laser generation module starts up, a low-temperature heat-conducting liquid causes the thermosensitive spring to remain unexpanded, and a main heat dissipation channel is closed to avoid an excessive cooling and shorten a preheating time; during an operation, as components heat up, a temperature of the heat-conducting liquid rises, causing the thermosensitive spring to expand and adjust a cooling liquid flow rate in the main heat dissipation channel, thereby achieving a dynamic temperature control and ensuring a stable laser output;

in addition, each control valve can respectively control a flow rate of a heat-conducting liquid entering a mixing chamber from each cooling plate. According to different heat generation characteristics and working states of a pump source, a working medium module, and a Q-switch module, an influence weight of each component temperature on a main heat dissipation can be adjusted to perform a targeted heat dissipation and improve a heat dissipation efficiency.

### BRIEF DESCRIPTION OF THE DRAWINGS

The present application is further illustrated by the accompanying drawings, but the embodiments in the drawings do not constitute any limitation on the present application. For a person of ordinary skill in the art, other drawings may also be obtained based on the following drawings without a creative effort.

FIG. 1 is a structural schematic diagram of the present application;

FIG. 2 is a structural schematic diagram of a laser unit of the present application;

FIG. 3 is an internal structural diagram of the laser unit of the present application;

FIG. 4 is a structural schematic diagram of a laser generation module of the present application;

FIG. 5 is a cross-sectional view of the laser generation module from a first perspective of the present application;

FIG. 6 is a cross-sectional view of the laser generation module from a second perspective of the present application;

FIG. 7 is a locally enlarged view of a portion A in FIG. 6;

FIG. 8 is a cross-sectional view of the laser generation module from a third perspective of the present application;

FIG. 9 is a locally enlarged view of a portion B in FIG. 8;

FIG. 10 is a cross-sectional view of the laser generation module from a fourth perspective of the present application;

FIG. 11 is a locally enlarged view of a portion C in FIG. 10;

FIG. 12 is a cross-sectional view of the laser generation module from a fifth perspective of the present application;

FIG. 13 is a locally enlarged view of a portion D in FIG. 12;

Wherein: 1, machine base; 11, worktable; 12, laser unit; 13, X-axis linear module; 14, gantry frame; 15, lifting seat; 16, Y-axis linear module; 17, Z-axis linear module; 21, laser seat; 22, laser generation module; 23, lens; 3, housing; 4, distributor; 41, main distribution channel; 42, main water inlet; 43, main water outlet; 44, first distribution channel; 45, second distribution channel; 46, third distribution channel; 471, mixing chamber; 472, mixing water outlet; 48, thermosensitive spring; 491, blocking portion; 492, connecting portion; 493, separation portion; 51, substrate; 52, semiconductor chip; 53, left cooling plate; 54, right cooling plate; 55, first water inlet; 56, first entry channel; 57, first adjustment channel; 6, working medium module; 61, second cooling plate; 62, second conduit; 63, second water inlet; 64, second entry channel; 65, second adjustment channel; 7, Q-switch module; 71, third cooling plate; 72, third conduit; 73, third water inlet; 74, third entry channel; 75, third adjustment channel; 81, first control valve; 82, second control valve; 83, third control valve; 84, threaded portion; 85, adjustment portion; 86, conical pin; 87, conical through hole; 91, first heat dissipation channel; 92, second heat dissipation channel; 93, heat conduction plate; 94, heat dissipation outlet.

### DESCRIPTION OF EMBODIMENTS

The present application is further described in combination with the following embodiments.

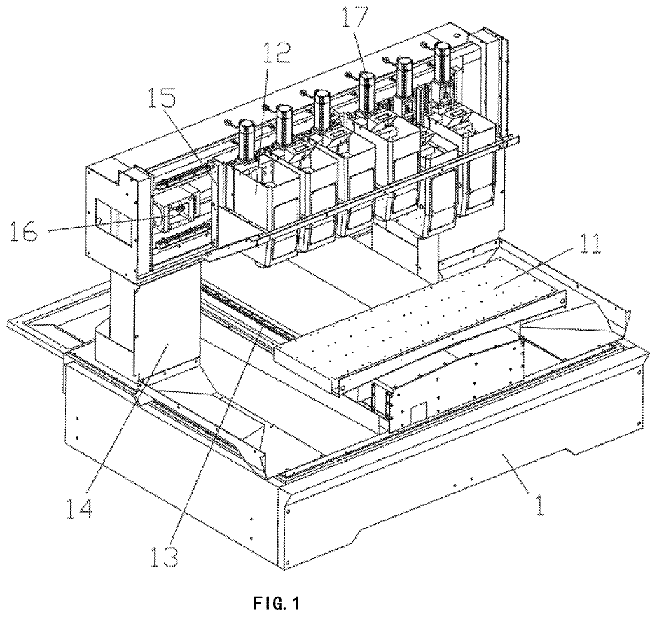

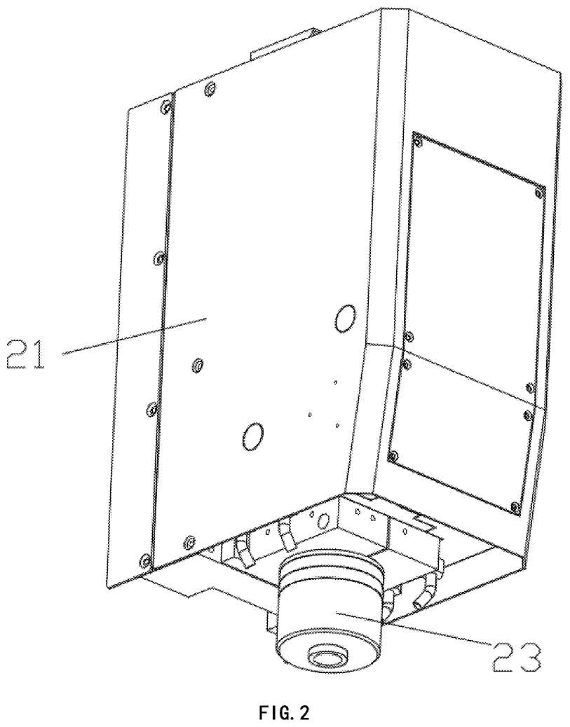

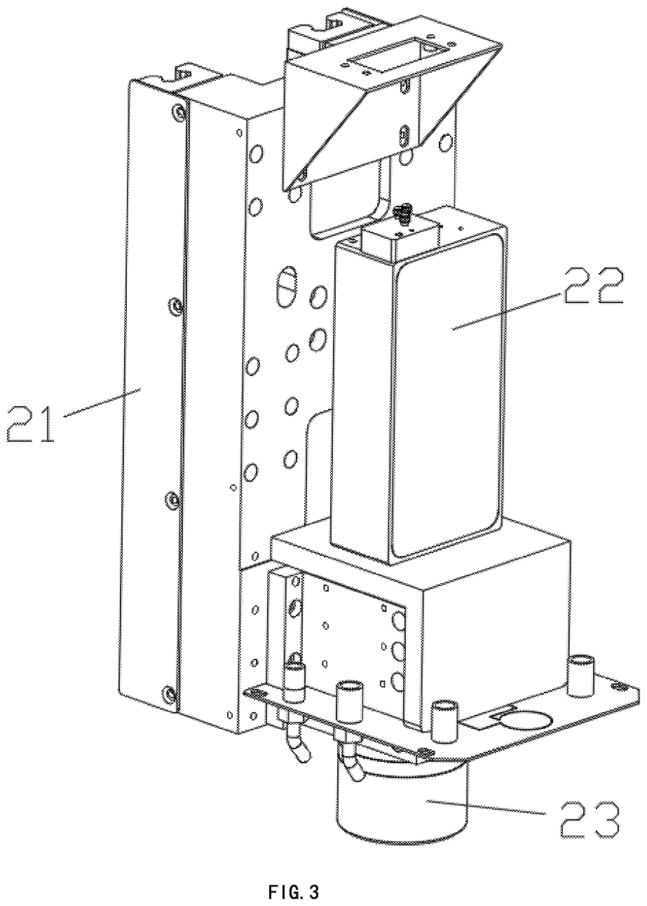

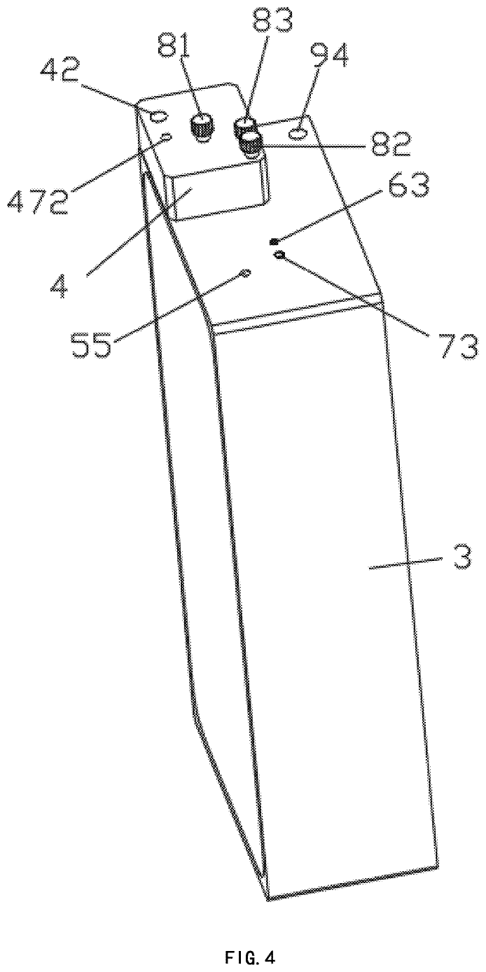

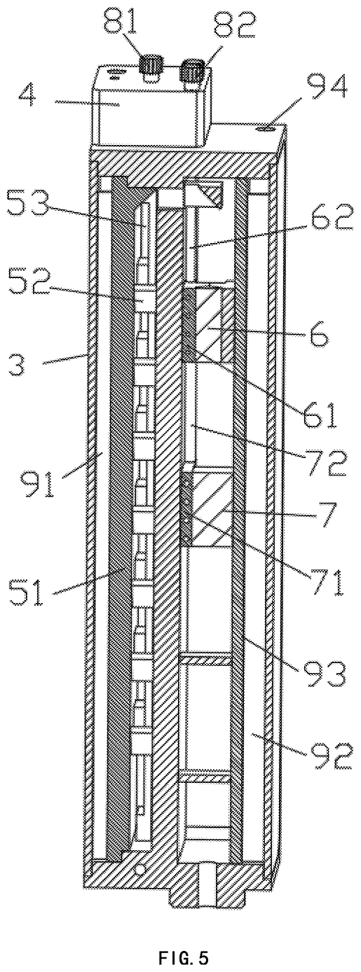

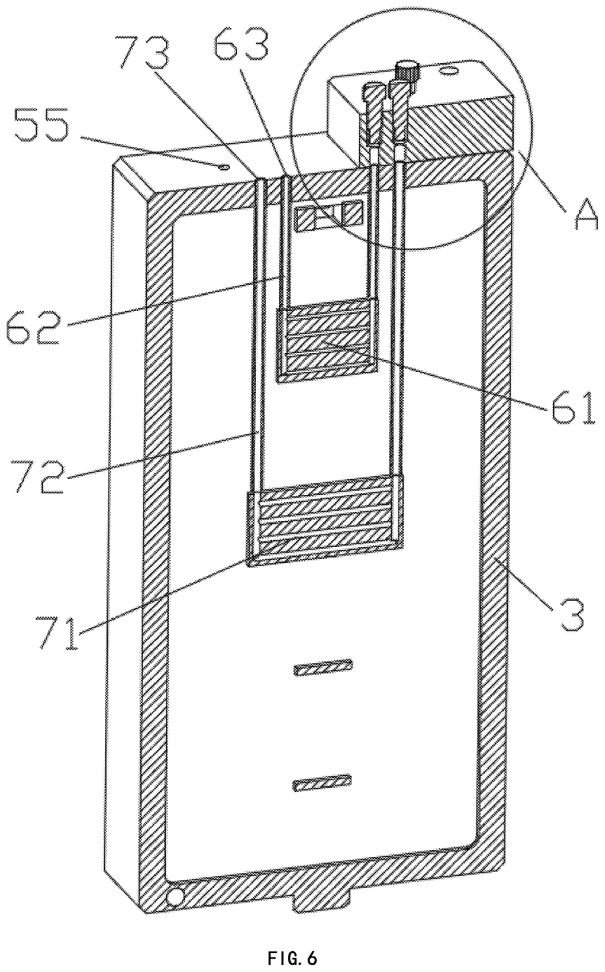

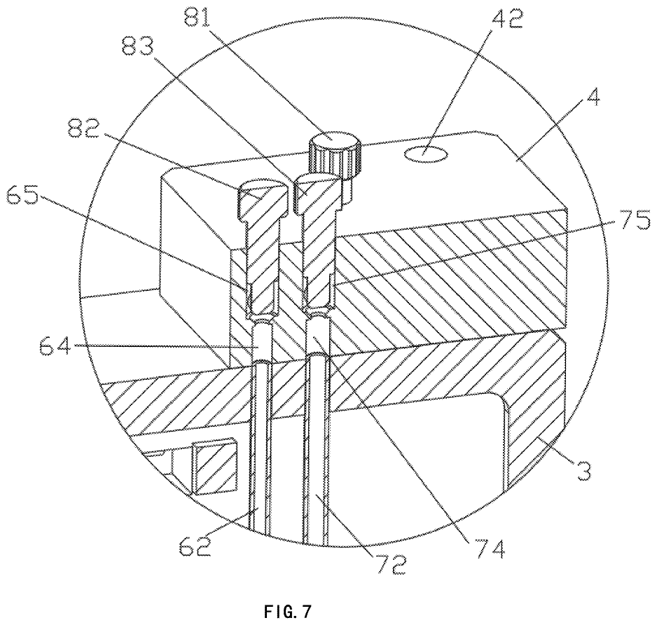

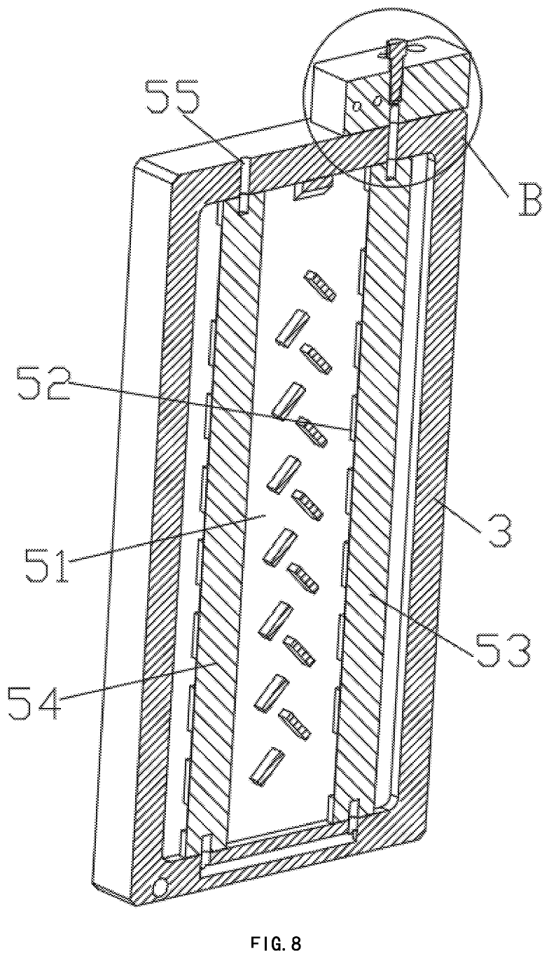

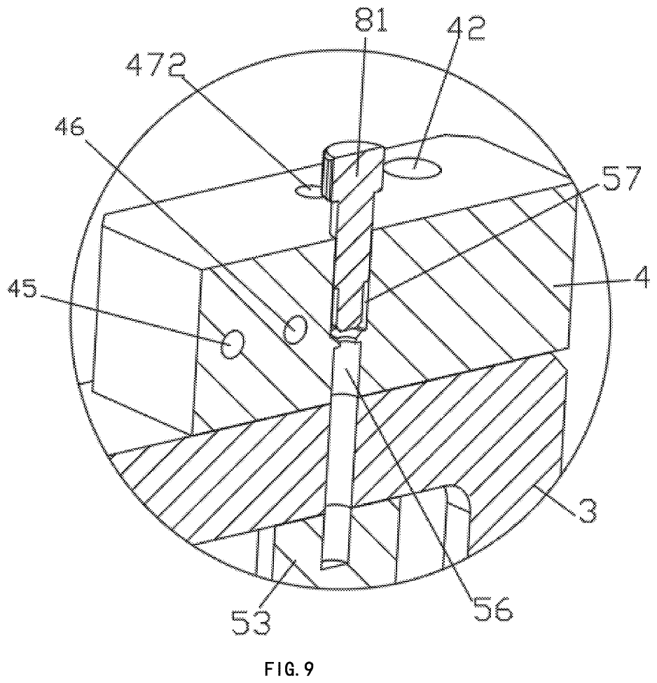

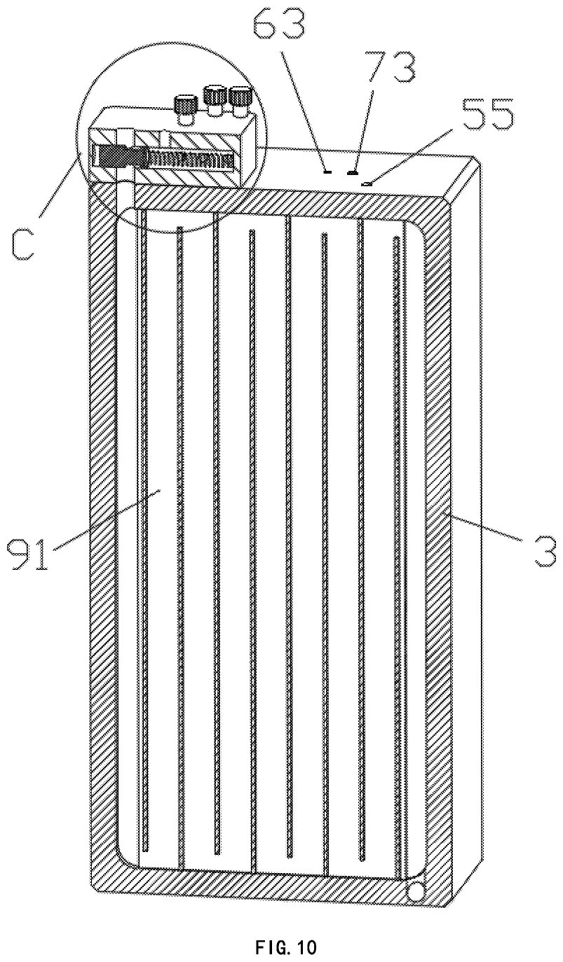

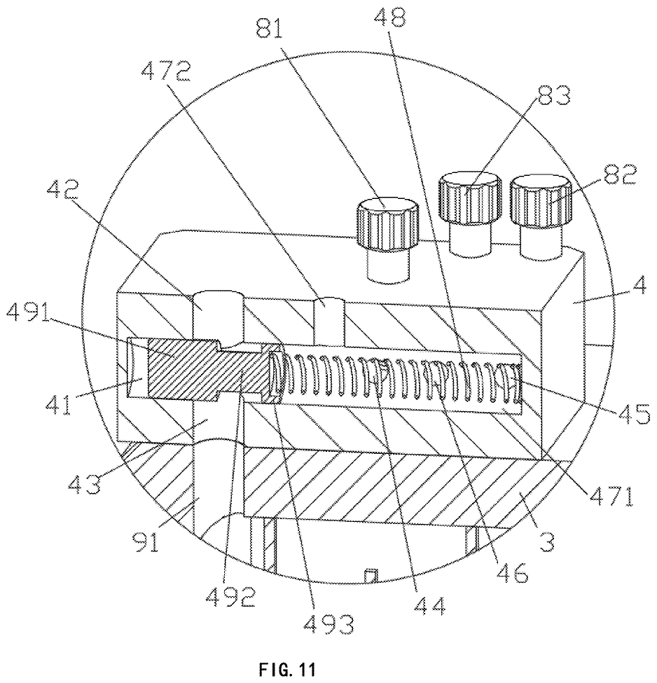

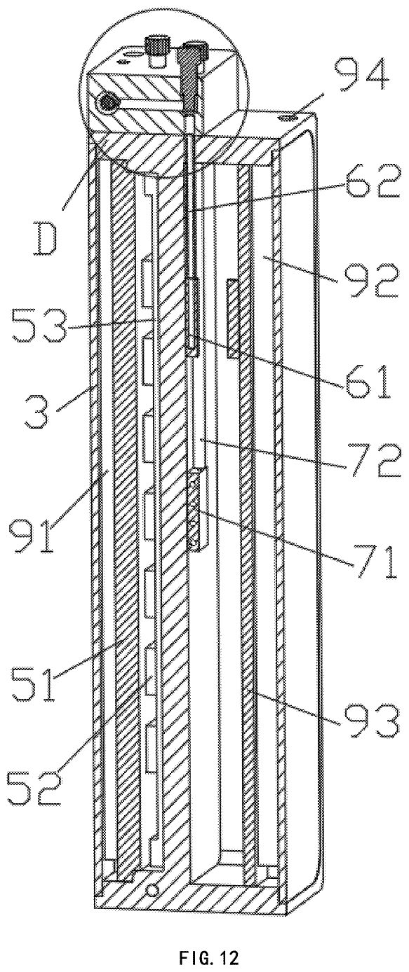

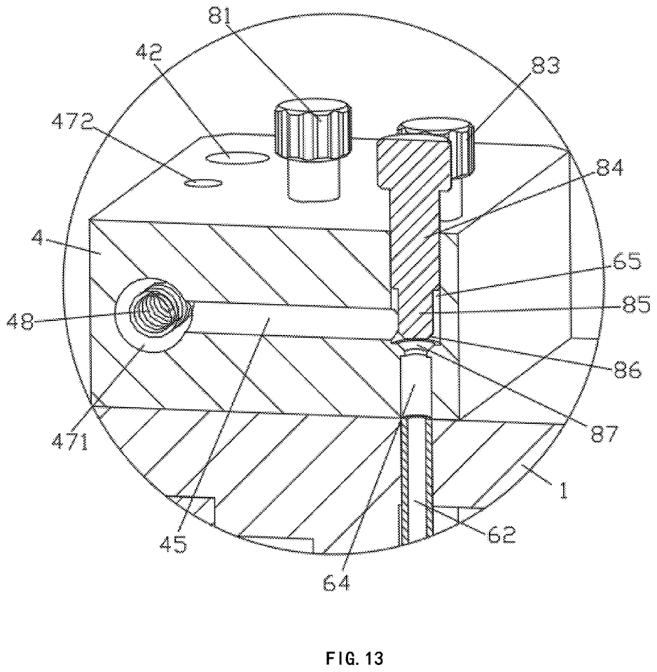

As shown in FIGS. 1 to 13, an eight-axis six-head linkage laser engraving machine with a cooling circulation structure according to this embodiment comprises a machine base 1; the machine base 1 is provided with a worktable 11 and a laser unit 12; the laser unit 12 is movably disposed on a top of the worktable 11; the laser unit 12 comprises a laser seat 21, a laser generation module 22 disposed in the laser seat 21, and a lens 23 disposed on the laser seat 21; and the lens 23 is disposed at a bottom of the laser generation module 22;

the laser generation module 22 comprises a housing 3 and a distributor 4; the distributor 4 is disposed on a top of the housing 3; the housing 3 is internally provided with a pump source, a working medium module 6, and a Q-switch module 7; the pump source is connected with a first cooling plate; the working medium module 6 is connected with a second cooling plate 61; the Q-switch module 7 is connected with a third cooling plate 71; and the housing 3 is provided with a main heat dissipation channel;

the distributor 4 is internally provided with a main distribution channel 41; the distributor 4 is provided with a main water inlet 42 and a main water outlet 43; the main water inlet 42 communicates with a top of the main distribution channel 41; the main water outlet 43 communicates with a bottom of the main distribution channel 41; the main water outlet 43 communicates with the main heat dissipation channel; the distributor 4 is internally provided with a first distribution channel 44 communicating with the first cooling plate, a second distribution channel 45 communicating with the second cooling plate 61, and a third distribution channel 46 communicating with the third cooling plate 71; the first distribution channel 44 is provided with a first control valve 81; the second distribution channel 45 is provided with a second control valve 82; the third distribution channel 46 is provided with a third control valve 83; the main distribution channel 41 is movably provided with a distribution valve along a length direction; a thermosensitive spring 48 is disposed between the distribution valve and the main distribution channel 41; and the first distribution channel 44, the second distribution channel 45, and the third distribution channel 46 respectively communicate with the main distribution channel 41.

Specifically, when the eight-axis six-head linkage laser engraving machine with a cooling circulation structure according to this embodiment is in a normal use, the first cooling plate is configured to provide an auxiliary cooling for the pump source, the second cooling plate 61 is configured to provide an auxiliary cooling for the working medium module 6, the third cooling plate 71 is configured to provide an auxiliary cooling for the Q-switch module 7, the main heat dissipation channel is configured to cool the entire housing 3, and the main water inlet 42 is externally connected to a cooling liquid;

a heat-conducting liquid flowing in the first cooling plate is able to flow into the main distribution channel 41 through the first distribution channel 44, a heat-conducting liquid flowing in the second cooling plate 61 is able to flow into the main distribution channel 41 through the second distribution channel 45, a heat-conducting liquid flowing in the third cooling plate 71 is able to flow into the main distribution channel 41 through the third distribution channel 46, that is, the heat-conducting liquid from the three cooling plates is able to be mixed in the main distribution channel 41, and when a mixed temperature rises, the thermosensitive spring 48 expands due to a heat, and the thermosensitive spring 48 pushes the distribution valve to move, thereby changing an opening between the main water inlet 42 and the main water outlet 43 to change a cooling liquid flow rate of the main heat dissipation channel.

Through the above configuration, when the laser generation module 22 starts to work, since temperatures of a heat-conducting liquid in the first cooling plate, in the second cooling plate 61, and in the third cooling plate 71 are all relatively low at this time, a temperature after a mixing of the heat-conducting liquid from the three cooling plates in the main distribution channel 41 is also relatively low, so the thermosensitive spring 48 has not expanded due to a heat. At this time, the distribution valve completely closes the main water inlet 42 and the main water outlet 43, so that a cooling liquid in the main heat dissipation channel cannot flow, and an overall cooling capacity is poor. At this time, the laser generation module 22 is able to quickly reach a working temperature.

During an operation of the laser generation module 22, temperatures of various components continuously rise, causing temperatures of a heat-conducting liquid in the first cooling plate, the second cooling plate 61, and the third cooling plate 71 to gradually increase, a temperature after a mixing of the heat-conducting liquid from the three cooling plates in the main distribution channel 41 also gradually rises, the thermosensitive spring 48 expands due to a heat, and the thermosensitive spring 48 pushes the distribution valve to move, thereby changing an opening between the main water inlet 42 and the main water outlet 43 to increase a cooling liquid flow rate of the main heat dissipation channel.

In addition, this embodiment is able to control a flow rate of a heat-conducting liquid from the first cooling plate entering the main distribution channel 41, a flow rate of a heat-conducting liquid from the second cooling plate 61 entering the main distribution channel 41, and a flow rate of a heat-conducting liquid from the third cooling plate 71 entering the main distribution channel 41 by adjusting the first control valve 81, the second control valve 82, and the third control valve 83, respectively, thereby changing a weight of a pump source temperature on a cooling liquid flow rate of the main heat dissipation channel, a weight of a working medium module 6 temperature on a cooling liquid flow rate of the main heat dissipation channel, and a weight of a Q-switch module 7 temperature on a cooling liquid flow rate of the main heat dissipation channel. For example, when the pump source is at a high power output, a heating rate of the pump source is much faster than in a low power working state. At this time, an opening of the first control valve 81 corresponding to the pump source may be increased. On one hand, after the first control valve 81 is increased, a heat-conducting liquid circulation of the first cooling plate accelerates and is able to take away more heat. On another hand, more of a high-temperature heat-conducting liquid from the first cooling plate enters the main distribution channel 41, which causes a temperature rise of a mixed heat-conducting liquid in the main distribution channel 41 to mainly depend on an amount of the high-temperature heat-conducting liquid entering from the first cooling plate, thereby causing a movement of the distribution valve to be mainly controlled by a working state of the pump source to prevent an output power attenuation of the pump source due to a poor heat dissipation.

In the eight-axis six-head linkage laser engraving machine with a cooling circulation structure according to this embodiment, the distribution valve comprises a blocking portion 491, a connecting portion 492, and a separation portion 493; the connecting portion 492 is disposed between the blocking portion 491 and the separation portion 493; the blocking portion 491, the connecting portion 492, and the separation portion 493 are all cylindrical structures; a radius of the connecting portion 492 is smaller than a radius of the blocking portion 491; the radius of the connecting portion 492 is smaller than a radius of the separation portion 493; the blocking portion 491 and the separation portion 493 are sealingly and movably disposed in the main distribution channel 41; the blocking portion 491 is configured to block the main water inlet 42 and the main water outlet 43; and the separation portion 493 is able to prevent a mixed heat-conducting liquid from entering the main water inlet 42 and the main water outlet 43. In the eight-axis six-head linkage laser engraving machine with a cooling circulation structure according to this embodiment, the thermosensitive spring 48 is disposed between an end of the separation portion 493 away from the connecting portion 492 and the main distribution channel 41; a mixing chamber 471 is formed between the end of the separation portion 493 away from the connecting portion 492 and the main distribution channel 41; the first distribution channel 44, the second distribution channel 45, and the third distribution channel 46 respectively communicate with the mixing chamber 471; and the distributor 4 is provided with a mixing water outlet 472 communicating with the mixing chamber 471.

Specifically, when the laser generation module 22 starts to work in the eight-axis six-head linkage laser engraving machine with a cooling circulation structure according to this embodiment, since temperatures of a heat-conducting liquid in the first cooling plate, the second cooling plate 61, and the third cooling plate 71 are all relatively low at this time, a temperature after a mixing of the heat-conducting liquid from the three cooling plates in the mixing chamber 471 is also relatively low, so the thermosensitive spring 48 has not expanded due to a heat. At this time, the blocking portion 491 of the distribution valve completely closes the main water inlet 42 and the main water outlet 43, so that a cooling liquid in the main heat dissipation channel cannot flow, and an overall cooling capacity is poor. At this time, the laser generation module 22 is able to quickly reach a working temperature.

During an operation of the laser generation module 22, temperatures of various components continuously rise, causing temperatures of a heat-conducting liquid in the first cooling plate, the second cooling plate 61, and the third cooling plate 71 to gradually increase. A temperature after a mixing of the heat-conducting liquid from the three cooling plates in the mixing chamber 471 also gradually rises, the thermosensitive spring 48 expands due to a heat, and the thermosensitive spring 48 pushes the distribution valve to move, causing the blocking portion 491 of the distribution valve to gradually open the main water inlet 42 and the main water outlet 43, while the connecting portion 492 does not block the main water inlet 42 and the main water outlet 43, thereby increasing a cooling liquid flow rate of the main heat dissipation channel.

In addition, this embodiment is able to control a flow rate of a heat-conducting liquid from the first cooling plate entering the mixing chamber 471, a flow rate of a heat-conducting liquid from the second cooling plate 61 entering the mixing chamber 471, and a flow rate of a heat-conducting liquid from the third cooling plate 71 entering the mixing chamber 471 by adjusting the first control valve 81, the second control valve 82, and the third control valve 83, respectively, thereby changing a weight of a pump source temperature on a cooling liquid flow rate of the main heat dissipation channel, a weight of a working medium module 6 temperature on the cooling liquid flow rate of the main heat dissipation channel, and a weight of a Q-switch module 7 temperature on the cooling liquid flow rate of the main heat dissipation channel.

In the eight-axis six-head linkage laser engraving machine with a cooling circulation structure according to this embodiment, the pump source comprises a substrate 51 and a semiconductor chip 52 disposed on the substrate 51; the first cooling plate comprises a left cooling plate 53 and a right cooling plate 54; a top of the left cooling plate 53 communicates with the first distribution channel 44; a bottom of the left cooling plate 53 communicates with a bottom of the right cooling plate 54; a top of the housing 3 is provided with a first water inlet 55 communicating with a top of the right cooling plate 54; and the left cooling plate 53 and the right cooling plate 54 respectively abut against the semiconductor chip 52.

Specifically, a heat-conducting liquid enters a top of the right cooling plate 54 from the first water inlet 55, passes through the right cooling plate 54 and then enters a bottom of the left cooling plate 53, then enters a first entry channel 56 from a top of the left cooling plate 53, enters the mixing chamber 471 through a first adjustment channel 57 and the first distribution channel 44, and finally discharges from the mixing water outlet 472; through the above configuration, an auxiliary cooling is able to be provided for the semiconductor chip 52 of the substrate 51, and a temperature change of the semiconductor chip 52 is able to be transmitted to the thermosensitive spring 48 in the mixing chamber 471 through a flow of the heat-conducting liquid, finally changing a cooling liquid flow rate of the main heat dissipation channel.

In the eight-axis six-head linkage laser engraving machine with a cooling circulation structure according to this embodiment, the housing 3 is internally provided with a second conduit 62 and a third conduit 72; a top of the housing 3 is provided with a second water inlet 63 and a third water inlet 73; one end of the second conduit 62 communicates with the second distribution channel 45; another end of the second conduit 62 communicates with the second water inlet 63 after passing through the second cooling plate 61; one end of the third conduit 72 communicates with the third distribution channel 46; and another end of the third conduit 72 communicates with the third water inlet 73 after passing through the third cooling plate 71.

Specifically, a heat-conducting liquid enters another end of the second conduit 62 from the second water inlet 63, then enters the second cooling plate 61, subsequently enters a second entry channel 64 from one end of the second conduit 62, enters the mixing chamber 471 through a second adjustment channel 65 and the second distribution channel 45, and finally discharges from the mixing water outlet 472. Through the above configuration, an auxiliary cooling is able to be provided for the working medium module 6, and a temperature change of the working medium module 6 is able to be transmitted to the thermosensitive spring 48 in the mixing chamber 471 through a flow of the heat-conducting liquid, finally changing a cooling liquid flow rate of the main heat dissipation channel.

A heat-conducting liquid enters another end of the third conduit 72 from the third water inlet 73, then enters the third cooling plate 71, subsequently enters a third entry channel 74 from one end of the third conduit 72, enters the mixing chamber 471 through a third adjustment channel 75 and the third distribution channel 46, and finally discharges from the mixing water outlet 472. Through the above configuration, an auxiliary cooling is able to be provided for the Q-switch module 7, and a temperature change of the Q-switch module 7 is able to be transmitted to the thermosensitive spring 48 in the mixing chamber 471 through a flow of the heat-conducting liquid, finally changing a cooling liquid flow rate of the main heat dissipation channel.

In the eight-axis six-head linkage laser engraving machine with a cooling circulation structure according to this embodiment, a top of the distributor 4 is provided with a first adjustment channel 57, a second adjustment channel 65, and a third adjustment channel 75; the first control valve 81 is movably disposed in the first adjustment channel 57; the second control valve 82 is movably disposed in the second adjustment channel 65; the third control valve 83 is movably disposed in the third adjustment channel 75; a bottom of the distributor 4 is provided with a first entry channel 56 communicating with the first cooling plate, a second entry channel 64 communicating with the second cooling plate 61, and a third entry channel 74 communicating with the third cooling plate 71; the first entry channel 56 communicates with a bottom of the first adjustment channel 57; the first distribution channel 44 communicates with a side of the first adjustment channel 57; the second entry channel 64 communicates with a bottom of the second adjustment channel 65; the second distribution channel 45 communicates with a side of the second adjustment channel 65; the third entry channel 74 communicates with a bottom of the third adjustment channel 75; and the third distribution channel 46 communicates with a side of the third adjustment channel 75.

In the eight-axis six-head linkage laser engraving machine with a cooling circulation structure according to this embodiment, a connection between the first entry channel 56 and the first adjustment channel 57, a connection between the second entry channel 64 and the second adjustment channel 65, and a connection between the third entry channel 74 and the third adjustment channel 75 are all provided with a conical through hole 87; the first control valve 81, the second control valve 82, and the third control valve 83 each comprise a threaded portion 84 and an adjustment portion 85 disposed at a bottom of the threaded portion 84; the first adjustment channel 57, the second adjustment channel 65, and the third adjustment channel 75 are respectively threadedly connected with the threaded portion 84; the threaded portion 84 and the adjustment portion 85 are both cylindrical structures; a radius of the adjustment portion 85 is smaller than a radius of the threaded portion 84; and a bottom of the adjustment portion 85 is provided with a conical pin 86 cooperating with the conical through hole 87.

Specifically, through the above configuration, this embodiment is able to change a depth of the adjustment portion 85 of each control valve in each adjustment channel by rotating the threaded portion 84 of each control valve, thereby changing a distance between the adjustment portion 85 and the conical through hole 87, thus adjusting a flow rate of each entry channel and each adjustment channel to achieve a purpose of changing a flow rate of a heat-conducting liquid from each cooling plate entering the mixing chamber 471.

In the eight-axis six-head linkage laser engraving machine with a cooling circulation structure according to this embodiment, the main heat dissipation channel comprises a first heat dissipation channel 91 and a second heat dissipation channel 92; the pump source is disposed on one side within the housing 3; another side within the housing 3 is provided with a heat conduction plate 93; the working medium module 6 and the Q-switch module 7 are both disposed on the heat conduction plate 93; the first heat dissipation channel 91 is disposed between the substrate 51 and the housing 3; the second heat dissipation channel 92 is disposed between the heat conduction plate 93 and the housing 3; a top of the first heat dissipation channel 91 communicates with the main water outlet 43; a bottom of the first heat dissipation channel 91 communicates with a bottom of the second heat dissipation channel 92; and a top of the housing 3 is provided with a heat dissipation outlet 94 communicating with a top of the second heat dissipation channel 92.

Specifically, a cooling liquid enters the main distribution channel 41 from the main water inlet 42, then enters a top of the first heat dissipation channel 91 through the main water outlet 43, and flows from a bottom of the first heat dissipation channel 91 to a bottom of the second heat dissipation channel 92, and finally flows out from a top of the second heat dissipation channel 92 to the heat dissipation outlet 94; through the above configuration, the pump source, the working medium module 6, and the Q-switch module 7 are able to be effectively cooled and dissipated.

In the eight-axis six-head linkage laser engraving machine with a cooling circulation structure according to this embodiment, the machine base 1 is provided with an X-axis linear module 13 configured to drive the worktable 11 to move along an X-axis direction. In the eight-axis six-head linkage laser engraving machine with a cooling circulation structure according to this embodiment, the worktable 11 is provided with a gantry frame 14; the gantry frame 14 is arranged with six lifting seats 15 along a Y-axis direction; the gantry frame 14 is provided with a Y-axis linear module 16 configured to drive the lifting seats 15 to move along the Y-axis direction; each lifting seat 15 is provided with a laser unit 12; and each lifting seat 15 is provided with a Z-axis linear module 17 configured to drive the laser unit 12 to move up and down.

Specifically, this embodiment achieves an eight-axis directional movement by providing the X-axis linear module 13, the Y-axis linear module 16, and six Z-axis linear modules 17; in addition, by providing six laser units 12, an overall work efficiency is able to be effectively improved.

Finally, it should be noted that the above embodiments are only used to illustrate a technical solution of the present application, rather than to limit a protection scope of the present application. Although the present application has been described in detail with reference to preferred embodiments, a person of ordinary skill in the art should understand that modifications or equivalent substitutions can be made to the technical solution of the present application without departing from an essence and a scope of the technical solution of the present application.

What is claimed is:

1. An eight-axis six-head linkage laser engraving machine with a cooling circulation structure, comprising:
a machine base 1;
wherein the machine base 1 is provided with a worktable 11 and a laser unit 12;
the laser unit 12 is movably disposed on a top of the worktable 11;
the laser unit 12 comprises a laser seat 21, a laser generation module 22 disposed in the laser seat 21, and a lens 23 disposed on the laser seat 21;
the lens 23 is disposed at a bottom of the laser generation module 22;
the laser generation module 22 comprises a housing 3 and a distributor 4;
the distributor 4 is disposed on a top of the housing 3;
the housing 3 is internally provided with a pump source, a working medium module 6, and a Q-switch module 7;
the pump source is connected with a first cooling plate;
the working medium module 6 is connected with a second cooling plate 61;
the Q-switch module 7 is connected with a third cooling plate 71;
the housing 3 is provided with a main heat dissipation channel;
the distributor 4 is internally provided with a main distribution channel 41;
the distributor 4 is provided with a main water inlet 42 and a main water outlet 43;
the main water inlet 42 communicates with a top of the main distribution channel 41;
the main water outlet 43 communicates with a bottom of the main distribution channel 41;
the main water outlet 43 communicates with the main heat dissipation channel;
the distributor 4 is internally provided with a first distribution channel 44 communicating with the first cooling plate, a second distribution channel 45 communicating with the second cooling plate 61, and a third distribution channel 46 communicating with the third cooling plate 71;
the first distribution channel 44 is provided with a first control valve 81;
the second distribution channel 45 is provided with a second control valve 82;
the third distribution channel 46 is provided with a third control valve 83;
the main distribution channel 41 is movably provided with a distribution valve along a length direction;
a thermosensitive spring 48 is disposed between the distribution valve and the main distribution channel 41; and
the first distribution channel 44, the second distribution channel 45, and the third distribution channel 46 respectively communicate with the main distribution channel 41.

2. The eight-axis six-head linkage laser engraving machine with a cooling circulation structure according to claim 1, wherein: the distribution valve comprises a blocking portion 491, a connecting portion 492, and a separation portion 493; the connecting portion 492 is disposed between the blocking portion 491 and the separation portion 493; the blocking portion 491, the connecting portion 492, and the separation portion 493 are all cylindrical structures; a radius of the connecting portion 492 is smaller than a radius of the blocking portion 491; the radius of the connecting portion 492 is smaller than a radius of the separation portion 493; the blocking portion 491 and the separation portion 493 are sealingly and movably disposed in the main distribution channel 41; and the blocking portion 491 is configured to block the main water inlet 42 and the main water outlet 43.

3. The eight-axis six-head linkage laser engraving machine with a cooling circulation structure according to claim 2, wherein: the thermosensitive spring 48 is disposed between an end of the separation portion 493 away from the connecting portion 492 and the main distribution channel 41; a mixing chamber 471 is formed between the end of the separation portion 493 away from the connecting portion 492 and the main distribution channel 41; the first distribution channel 44, the second distribution channel 45, and the third distribution channel 46 respectively communicate with the mixing chamber 471; and the distributor 4 is provided with a mixing water outlet 472 communicating with the mixing chamber 471.

4. The eight-axis six-head linkage laser engraving machine with a cooling circulation structure according to claim 1, wherein: the pump source comprises a substrate 51 and a semiconductor chip 52 disposed on the substrate 51; the first cooling plate comprises a left cooling plate 53 and a right cooling plate 54; a top of the left cooling plate 53 communicates with the first distribution channel 44; a bottom of the left cooling plate 53 communicates with a bottom of the right cooling plate 54; a top of the housing 3 is provided with a first water inlet 55 communicating with a top of the right cooling plate 54; and the left cooling plate 53 and the right cooling plate 54 respectively abut against the semiconductor chip 52.

5. The eight-axis six-head linkage laser engraving machine with a cooling circulation structure according to claim 1, wherein: the housing 3 is internally provided with a second conduit 62 and a third conduit 72; a top of the housing 3 is provided with a second water inlet 63 and a third water inlet 73; one end of the second conduit 62 communicates with the second distribution channel 45; another end of the second conduit 62 communicates with the second water inlet 63 after passing through the second cooling plate 61; one end of the third conduit 72 communicates with the third distribution channel 46; and another end of the third conduit 72 communicates with the third water inlet 73 after passing through the third cooling plate 71.

6. The eight-axis six-head linkage laser engraving machine with a cooling circulation structure according to claim 1, wherein: a top of the distributor 4 is provided with a first adjustment channel 57, a second adjustment channel 65, and a third adjustment channel 75; the first control valve 81 is movably disposed in the first adjustment channel 57; the second control valve 82 is movably disposed in the second adjustment channel 65; the third control valve 83 is movably disposed in the third adjustment channel 75; a bottom of the distributor 4 is provided with a first entry channel 56 communicating with the first cooling plate, a second entry channel 64 communicating with the second cooling plate 61, and a third entry channel 74 communicating with the third cooling plate 71; the first entry channel 56 communicates with a bottom of the first adjustment channel 57; the first distribution channel 44 communicates with a side of the first adjustment channel 57; the second entry channel 64 communicates with a bottom of the second adjustment channel 65; the second distribution channel 45 communicates with a side of the second adjustment channel 65; the third entry channel 74 communicates with a bottom of the third adjustment channel 75; and the third distribution channel 46 communicates with a side of the third adjustment channel 75.

7. The eight-axis six-head linkage laser engraving machine with a cooling circulation structure according to claim 6, wherein: a connection between the first entry channel 56 and the first adjustment channel 57, a connection between the second entry channel 64 and the second adjustment channel 65, and a connection between the third entry channel 74 and the third adjustment channel 75 are all provided with a conical through hole 87; the first control valve 81, the second control valve 82, and the third control valve 83 each comprise a threaded portion 84 and an adjustment portion 85 disposed at a bottom of the threaded portion 84; the first adjustment channel 57, the second adjustment channel 65, and the third adjustment channel 75 are respectively threadedly connected with the threaded portion 84; the threaded portion 84 and the adjustment portion 85 are both cylindrical structures; a radius of the adjustment portion 85 is smaller than a radius of the threaded portion 84; and a bottom of the adjustment portion 85 is provided with a conical pin 86 cooperating with the conical through hole 87.

8. The eight-axis six-head linkage laser engraving machine with a cooling circulation structure according to claim 4, wherein: the main heat dissipation channel comprises a first heat dissipation channel 91 and a second heat dissipation channel 92; the pump source is disposed on one side within the housing 3; another side within the housing 3 is provided with a heat conduction plate 93; the working medium module 6 and the Q-switch module 7 are both disposed on the heat conduction plate 93; the first heat dissipation channel 91 is disposed between the substrate 51 and the housing 3; the second heat dissipation channel 92 is disposed between the heat conduction plate 93 and the housing 3; a top of the first heat dissipation channel 91 communicates with the main water outlet 43; a bottom of the first heat dissipation channel 91 communicates with a bottom of the second heat dissipation channel 92; and a top of the housing 3 is provided with a heat dissipation outlet 94 communicating with a top of the second heat dissipation channel 92.

9. The eight-axis six-head linkage laser engraving machine with a cooling circulation structure according to claim 1, wherein: the machine base 1 is provided with an X-axis linear module 13 configured to drive the worktable 11 to move along an X-axis direction.

10. The eight-axis six-head linkage laser engraving machine with a cooling circulation structure according to claim 1, wherein: the worktable 11 is provided with a gantry frame 14; the gantry frame 14 is arranged with six lifting seats 15 along a Y-axis direction; the gantry frame 14 is provided with a Y-axis linear module 16 configured to drive the lifting seats 15 to move along the Y-axis direction; each lifting seat 15 is provided with a laser unit 12; and each lifting seat 15 is provided with a Z-axis linear module 17 configured to drive the laser unit 12 to move up and down.
